(19) United States
(12) Patent Application Publication
(10) Pub. No.: US 2011/0220193 A1
(43) Pub. Date: Sep. 15, 2011

(54) PHOTOVOLTAIC CELL WITH DISTRIBUTED EMITTER IN A SUBSTRATE, AND METHOD FOR MANUFACTURE OF SUCH A CELL

(75) Inventors: Jean-Paul Garandet, Le Bourget Du Lac (FR); Luc Federzoni, Bourgoin-Jallieu (FR); Yannick Veschetti, Concarneau (FR)

(73) Assignee: Commissariat A L'energie Atomique ET Aux Ene Alt, Paris (FR)

(21) Appl. No.: 13/129,582

(22) PCT Filed: Nov. 20, 2009
(86) PCT No.: PCT/EP2009/065521

§ 371 Date: May 17, 2011

(30) Foreign Application Priority Data
Nov. 21, 2008 (FR) 08 57926

(51) Int. Cl. H01L 31/0352; H01L 31/18

(52) U.S. Cl. 136/255; 438/57; 257/E31.037

(57) ABSTRACT

A photovoltaic cell including a substrate composed of a semiconductor of a first type of conductivity including two main faces substantially parallel with one another, the substrate including a plurality of blind holes, openings of which are positioned in a single one of the two main faces, and the blind holes filled by a semiconductor of a second type of conductivity opposed to the first type of conductivity forming an emitter of the photovoltaic cell. The substrate forms a base of the photovoltaic cell. First collector pins composed of a semiconductor of the second type of conductivity are in contact with the emitter of the photovoltaic cell, and second collector pins composed of a semiconductor of the first type of conductivity are in contact with the substrate and interdigitated with the first collector pins.

### TECHNICAL FIELD

The invention concerns the field of photovoltaic cells, and notably that of photovoltaic cells with rear contacts, i.e. with contacts located on the face of the cell not receiving the photons. The invention also concerns the manufacture of photovoltaic cells from semiconductors of lower quality than the standard quality used in microelectronics.

### STATE OF THE PRIOR ART

Photovoltaic cells are principally manufactured from monocrystalline or polycrystalline silicon substrates obtained by solidifying ingots from a liquid silicon bath, and then by cutting wafers of this ingot to obtain the substrates or plates. Various techniques for depositing on these silicon substrates are then used in a clean room to produce the photovoltaic cells.

During production of a photovoltaic cell by the traditional technology called “homojunction”, the crystallised silicon ingots are firstly cut into wafers on which the cells are manufactured. These wafers are then textured by chemical attack to improve the trapping of the light by the photovoltaic cells which will be manufactured from these wafers. P-n junctions are then made by gaseous diffusion in these wafers. A PECVD deposit is then made to improve the antiglare properties of the cell and to passivate the recombining defects. Conducting layers are then deposited by screen printing on both faces to allow the photogenerated carriers to be collected, and the electrical contacts of the photovoltaic cell to be made.

However, with this type of technology known as “homojunction” the energy efficiencies attained industrially are limited, typically of the order of 15%, even with a “microelectronics” quality basic silicon.

To obtain efficiencies higher than 20% it is necessary to use photovoltaic cells of different structures, such as photovoltaic cells with heterojunctions (amorphous Si/crystalline Si) and/or cells of the RCC (Rear Contact Cell) type, which notably enable the shade relating to the presence of collecting conductors on the front face of the cell to be overcome (all the contacts are on the rear face of the cell).

Whatever the type of cell produced, the attainment of advantageous energy efficiencies presupposes that a maximum number of photogenerated minority carriers in the core of the cell will be able to reach the p-n junction in order to be collected, and therefore that their diffusion length is higher than the thickness of the wafer. This is very particularly so in the case of RCC cells, since the carriers are principally generated in the first microns of the lit silicon, in the area of the front face of the cell, and must therefore traverse the entire wafer before being collected. Production of a cell of the RCC type therefore requires the use of mono-crystals produced from silicon of microelectronics quality, which has a high diffusion length of the minority carriers, but which has the major disadvantage that it is costly.

Other types of less costly silicon exist, but have a lesser degree of purity, giving a lower diffusion length of the minority carriers. These silicons of lower quality cannot therefore be used for the production of RCC type cells.

There are also photovoltaic cells of the EWT (Emitter Wrap Through) type. These cells are produced from a silicon wafer, for example of the p type. Holes (the diameter of which is equal to approximately 60 μm, and at intervals of approximately 2 mm) are produced by laser engraving through the silicon wafer. The emitter of the cell is then formed by the production of a n+ type layer by gaseous diffusion on the front face, in the walls of the holes, and also on part of the cell's rear face. Thus, the p-n+ junction is divided in the volume of the cell of the zones, enabling the distance to be travelled by a minority carrier before it is collected to be reduced.

Such EWT cells have, however, the major disadvantage that they have a high manufacturing cost as a consequence of their production, which must necessarily take place in a clean room, and of the use of a laser for the production of the holes in the substrate.

### Account of the Invention

One aim of the present invention is to propose a new architecture for a photovoltaic cell optimising the collection and transport of the minority charge carriers in the photovoltaic cell, the cost of production of which is lower, and which can be produced from semiconductors of lower quality than microelectronics quality.

To accomplish this the present invention proposes a photovoltaic cell including a substrate composed of a semiconductor of a first type of conductivity, having two substantially parallel main faces, one relative to the other, where the substrate includes a plurality of blind holes, the openings of which are located in a single one of the main faces, and where the blind holes are filled by a semiconductor of a second type of conductivity, opposed to the first type of conductivity forming the emitter of the photovoltaic cell, and where the substrate forms the base of the photovoltaic cell.

The emitter of this photovoltaic cell is distributed in the form of several semi-conducting portions distributed in blind holes, in the core of the substrate. Thus, in comparison with the existing architectures of photovoltaic cells, this arrangement of p-n junctions in the photovoltaic cell enables the minority charge carriers to be collected and transported within the photovoltaic cell to be optimised, thus allowing the use of semiconductors of quality inferior to microelectronics quality for its production, such as, for example, semiconductor powders blended with polymers. This cell may therefore be produced at low cost using, for example, techniques derived from microplasturgy.

In addition, compared to photovoltaic cells of the EWT type, the photovoltaic cell according to the invention offers greater possibilities for adjusting the dimensions, the positionings and the spacing of the portions of semiconductor forming the emitter of the cell. Compared to EWT technology this photovoltaic cell architecture also allows the use of low levels of doping of the semiconductors for equivalent conductance.

Each blind hole may have a central axis of symmetry substantially perpendicular to the two main faces of the substrate. The emitter of the cell is thus formed by lengthways portions of semiconductor positioned in the substrate of the photovoltaic cell.

Each blind hole may include, in a plane passing through the main face of the substrate where the openings of the blind holes are located, a section of area greater than the area of the bottom wall of the said blind hole. Thus, by choosing such blind holes, and therefore such portions of semiconductor to form the emitter of the photovoltaic cell, the area of the section of these blind holes varies with the height of the blind hole in the substrate, to take account of the spectral absorption of the incident photons by the semiconductor positioned in the substrate, which enables transport of the minority charge carriers to be improved.

In this case, for each blind hole, the ratio between the area of the section of the said blind hole in the area of the plane passing through the main face of the substrate where the openings of the blind holes are located and the area of the bottom wall of the said blind hole may be between 1 and 3.

Each blind hole may have a substantially truncated conical or ogive shape.

Each blind hole may include, in a plane parallel to one of the main faces of the substrate, a section of polygonal shape or, for example, a star shape. Thus, by choosing particular profiles for the portions of semiconductor forming the emitter of the cell, the probability of collecting the minority charge carriers is increased by increasing the area of the emitter compared to a given volume in the substrate, by means of original transverse shapes of these semiconducting portions forming the emitter of the photovoltaic cell.

At least one of the main faces of the substrate may be structured, improving by this means the trapping of the light by the photovoltaic cell.

The concentration of doping atoms, or carrier atoms, per cubic centimetre in the semiconductor of the second type of conductivity of the emitter may be between 10¹⁶ and 10²¹, and preferably between 10¹⁸ and 10²⁰. The concentration of doping atoms per cubic centimetre in the semiconductor of the first type of conductivity of the substrate may be between 10¹⁵ and 10¹⁸, and preferably between 10¹⁶ and 10¹⁷.

Advantageously, the thickness of the substrate may be less than 300 μm and the depth of each blind hole may advantageously be greater than half the thickness of the substrate.

The photovoltaic cell may also include, on the main face of the substrate where the openings of the blind holes are located, first collector pins composed of at least one semiconductor of the second type of conductivity, in contact with the emitter of the cell, and second collector pins composed of at least one semiconductor of the first type of conductivity, in contact with the substrate and interdigitated with the first collector pins.

In this case, the concentrations of doping atoms per cubic centimetre in the semiconductors of the first type of conductivity of the second collector pins and of the second type of conductivity of the first collector pins may be between 10¹⁹ and 10²¹.

The invention also concerns a method for producing a photovoltaic cell, including at least the following steps:

a) production of a substrate composed of a semiconductor of a first type of conductivity having two main faces which are substantially parallel one with the other,

b) production of a plurality of blind holes in the substrate, such that the openings of the blind holes are positioned in one only of the two main faces,

c) filling of the blind holes by a material composed of a semiconductor of a second type of conductivity, opposed to the first type of conductivity, forming the emitter of the photovoltaic cell.

Step a) may be implemented by an injection of a material composed of a semiconductor of a first type of conductivity into a mould.

In the course of this method it is possible to keep the substrate in the initial mould, removing the base of the latter to facilitate all problems of alignment.

Step c) of filling may also product, on the main face of the substrate where the openings of the blind holes are located, and through a first mask placed against the said face of the substrate having the openings of the blind holes, first collector pins composed of at least one semiconductor of the second type of conductivity in contact with the emitter of the cell, and also including after step c) the removal of the first mask and the production of second collector pins composed of at least one semiconductor of the first type of conductivity in contact with the substrate and interdigitated with the first collector pins by injection through a second mask placed against the said face of the substrate where the openings of the blind holes are located.

The substrate and/or the emitter and/or the collector pins may be produced from a blend of materials composed of semiconductor and polymers powders, and the method may also include, after the step c) of filling, a step of debinding of the blend undertaken at a temperature of between approximately 300° C. and 600° C., over a period of between approximately 12 hours and 36 hours, and a step of fritting of the powders obtained after debinding accomplished at a temperature of between approximately 1000° C. and 1350° C., over a period of between approximately 1 hour and 8 hours.

The step of debinding and/or the step of fritting may be accomplished in a reducing atmosphere, for example in a hydrogen atmosphere.

### BRIEF DESCRIPTION OF THE ILLUSTRATIONS

The present invention will be better understood on reading the description of examples of embodiment given, purely as an indication and in no way limiting, making reference to the appended illustrations in which:

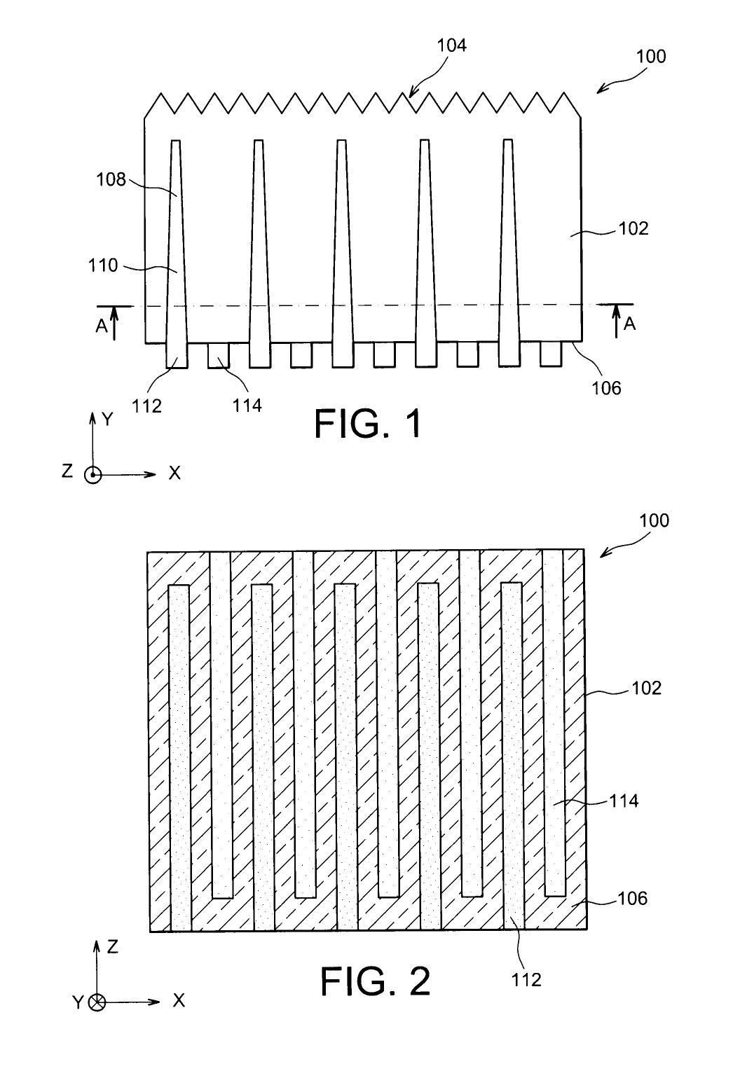

FIG. 1 represents a partial view, in section and in profile, of a photovoltaic cell forming the subject of the present invention, according to a particular embodiment,

FIG. 2 represents a partial view from beneath of a photovoltaic cell forming the subject of the present invention, according to a particular embodiment,

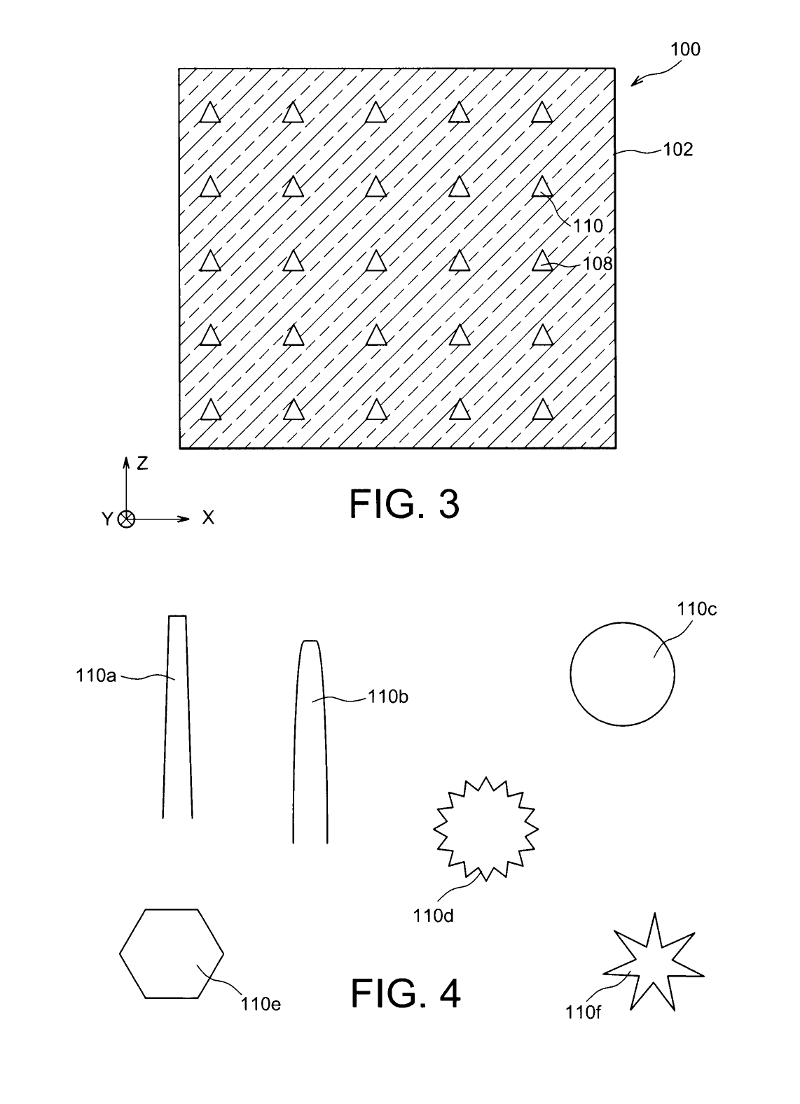

FIG. 3 represents a partial section view of a photovoltaic cell forming the subject of the present invention, according to a particular embodiment,

FIG. 4 represents examples of profiles and sections of blind holes produced in substrates of photovoltaic cells forming the subject of the present invention.

Identical, similar or equivalent parts of the different figures described below bear the same numerical references, to facilitate moving from one figure to another.

The different parts represented in the figures are not necessarily represented with a uniform scale, in order to make the figures more readable.

The various possibilities (variants and embodiments) must be understood as not being mutually exclusive, and able to be combined with one another.

### DETAILED ACCOUNT OF PARTICULAR EMBODIMENTS

Reference is made firstly to FIG. 1, which represents a partial view, in section and in profile, of a photovoltaic cell 100 according to a particular embodiment.

Photovoltaic cell 100, here of the p type, includes a substrate 102 composed of p type silicon. This substrate 102 includes a front face 104 intended to receive the light rays, and a rear face 106. In the example of FIG. 1 the front face 104 is textured in order better to trap the light arriving in the photovoltaic cell 100. In a variant embodiment the rear face 106 could also be structured, whether or not in a similar manner to the front face 104. The thickness of the substrate 102 is, for example, of between approximately 50 μm and 300 μm, and advantageously of between approximately 100 μm and 200 μm.

Blind holes 108 are formed in the substrate 102, each blind hole 108 having an opening in the rear face 106 of the substrate 102. As represented in FIG. 1, the blind holes 108 have profiles such that the section area of the blind holes 108 in the area of the rear face 106 is greater than the area of the bottom wall of the blind holes 108. FIG. 3, which is a section view of the photovoltaic cell 100 in the axis AA represented in FIG. 1, enables it to be seen that the blind holes 108 have, in this case, a section, in a plane parallel to the rear face 106, of triangular shape.

The blind holes 108 are filled by a semiconductor 110, in this case n+ type silicon. Thus, the portions of silicon 110 form the emitter of the photovoltaic cell 100 and the substrate 102 forms the base of the photovoltaic cell 100. Thus, p-n junctions distributed throughout the volume of the photovoltaic cell 100 are obtained.

The collection of the current generated in the photovoltaic cell 100 is accomplished by first collector pins 112, composed of n+ type silicon, and in contact with the portions of silicon 110, and which are interdigitated with second collector pins 114, composed of p+ type silicon, and in contact with the rear face 106 of the substrate 102 (see FIGS. 1 and 2).

The sections of the blind holes 108, in a plane parallel to one of the main faces 104 and 106 of the substrate 102, may be of a shape other than triangular, for example circular (see, for example, section 110c represented in FIG. 4). However, the sections of the blind holes 108 are preferably chosen of a shape other than circular, for example triangular as in FIG. 3, square, star-shaped (see, for example, sections 110d and 110f represented in FIG. 4), or polygonal, whether regular or irregular (see, for example, the octagonal section 110e represented in FIG. 4). These shapes enable the area of contact between the semiconductor 110 located in the blind holes 108 (the emitter) and the substrate 102 to be increased, which enables the probability of collection of the minority charge carriers in the photovoltaic cell 100 to be increased. For a given volume, a section of triangular shape enables the area of the emitter relative to a section of circular shape to be increased by approximately 30%. Again in comparison to a section of circular shape, an increase of area close to a factor 2 is obtained with a section of a regular hexagram shape, constituted by superimposing two equilateral triangles. Finally, if required, more complex shapes may be envisaged (polygons, whether regular or irregular, with n sides, or the superimposition of triangles and/or stars with n branches).

Depending on the quality of the semiconductor used, and notably its diffusion length, the distance between two adjacent portions of semiconductor 110, corresponding to the distance between two adjacent blind holes 108, may be between approximately 40 μm and 300 μm, and preferably between 60 μm and 100 μm.

In the example of FIG. 1, the blind holes 108 have a profile such that the dimensions of the sections of the blind holes 108 are reduced regularly as a function of the distance of the section relative to the rear face 106, for example a cone-shaped profile 110a (FIG. 4). In a variant, the blind holes 108 may have profiles of different shapes such as, for example, a truncated ogival shape (reference 110b in FIG. 4), in which the reduction of the dimensions of the sections is not regular along the entire length of the profile, but takes place principally in the bottom of the blind holes 108. It is also possible for the blind holes 108 to have profiles of different shapes (for example, cylindrical shape, i.e. the dimensions of the sections are identical along the entire length of the profile). Advantageously, each blind hole 108 includes, in a plane passing through the rear face 106, a section of area greater than the area of the bottom wall of the said blind hole 108, as is the case with the example of FIG. 1. Thus, the areas of the sections of the blind holes 108 vary with the height in the photovoltaic cell 100 to take account of the spectral absorption of the incident photons by the semiconductor material of the substrate 102. It is possible, for example, to have a ratio between the area of the section of the hole 108 in the area of the rear face 106 and the area of the bottom wall of the hole 108 of between approximately 1 and 3, and preferably of between approximately 1.2 and 2. The value of this ratio is chosen notably in accordance with the light source via the graph of absorption of the photons in the material used.

To limit the loss of active volume relating to the high recombining activity of the n+ zones formed by the portions of silicon 110, it is possible to limit as far as possible the volumes of the blind holes 108, whilst taking account of the technological constraints relating to the production of the blind holes 108 for the shape factor of the holes. The ratio between the height, i.e. the dimension in the y axis represented in FIG. 1, and the dimension of one of the sides (or of the diameter in the case of a circle) of a section of one of the blind holes 108 may, for example, be less than or equal to 10. In addition, the height of the portions of semiconductor, corresponding to the depth of the blind holes 108, is at least equal to half the thickness of the substrate 102.

The photovoltaic cell 100 described above is of the p type, i.e. includes p-n junctions formed by a substrate 102 composed of p type silicon and n+ type silicon 110 in the blind holes 108. In a variant the photovoltaic cell 100 described could be of the n type, i.e. including n-p junctions formed by a substrate 102 composed of n type silicon and p+ type silicon 110 in the blind holes 108. In addition, the semiconductor used for production of the photovoltaic cell 100 may be a semiconductor other than silicon, for example germanium. In the example described above, the collector pins 112, 114 are therefore respectively of types n+ and p+.

Generally, the substrate (of type p or n) has a concentration of doping atoms per cubic centimetre of between 10¹⁵ and 10¹⁸, and advantageously of between 10¹⁶ and 10¹⁷. The emitter has a concentration of doping atoms per cubic centimetre of between 10¹⁶ and 10²¹, and advantageously of between 10¹⁸ and 10²⁰. The collector pins have concentrations of doping atoms higher than those of the semiconductors with which they make contact. Thus, the first collector pins have a concentration of doping atoms per cubic centimetre of between 10¹⁹ and 10²¹, and advantageously of between 10²⁰ and 10²¹. If the semiconductor forming the emitter has a sufficiently high concentration it may also be suitable to constitute the second collector pins. These second collector pins (base) may therefore have a concentration of doping atoms per cubic centimetre of between approximately 10¹⁹ and 10²¹, and advantageously of between 5.10¹⁹ and 5.10²⁰.

A method is now described for production of the photovoltaic cell 100. This method uses low-cost technologies derived from microplasturgy, using stock blends containing silicon powders in a polymer carrier matrix.

For the production of the p type photovoltaic cell 100, 3 stock blends, or fillers, are firstly prepared, composed of p type, p+ type and n+ type silicon powders and polymers which, in particular, protect the silicon powders from their natural oxidation. The carrier polymers of these blends are of the polyolefin type, based on alkene-type monomers. Copolymers of several polyalkenes may also be used. In the example described here, the silicon powders are blended with polyethylene, and the volume fraction of silicon powders is approximately equal to 50%. In this example embodiment the p type filler has a boron atom concentration per cubic centimetre equal to approximately 5.10¹⁶. The p+ type filler has a boron atom concentration per cubic centimetre equal to approximately 2.10²⁰. Lastly, the n+ type filler has a phosphorus atom concentration per cubic centimetre equal to approximately 2.10²⁰.

The first step of the method consists in injecting the p type filler into a mould to form the substrate 102. When it is desired to produce a textured front face the mould may reproduce the desired texture for this front face. Advantageously, it is also possible to structure the rear face 106 of the cell 100 to improve further the optics of the cell 100. The height of the mould may be slightly higher than the desired thickness of the substrate 102. In the example described here the mould has lateral dimensions (corresponding to dimensions in the X and Z axes represented in FIG. 2) equal to approximately 10 cm, and a height equal to approximately 250 μm.

The lower part of the mould, i.e. the bottom of the mould against which is located the rear face 106 of the substrate 102, is removed, and the substrate 102 is then printed by a matrix to form, collectively, the blind holes 108 in the substrate 102. In the example described here, for a material of diffusion length equal to approximately 100 μm and a substrate of 250 μm thickness, this substrate 102 is printed by a nickel-based matrix which may have pins (intended to be sunk into the substrate 102 to form the blind holes 108), having the shape of a truncated cone, and of triangular-shaped section, where the side of the equilateral triangle has a dimension changing from 30 μm to 40 μm between the top and bottom of the hole. The blind holes 108 are produced with a depth equal to approximately 200 μm, and spaced relative to one another at a distance equal to approximately 200 μm. The spacing will generally be chosen according to the quality of the semiconductor constituting the substrate: it will be advantageously less than twice the value of the diffusion length of the minority carriers

A first mask, which leaves exposed only the positions of the collector pins 112 intended to be in contact with the portions of semiconductor 110, is then applied against the rear face 106, and the n+ filler is injected into the blind holes 108 to form the portions of semiconductor 110 forming the emitter of the photovoltaic cell 100. This mask has a certain height, for example equal to approximately 20 μm, to form also the first collector pins 112.

The first mask is removed, and a second mask enabling the second collector pins 114 to be produced from the p+ silicon filler is then applied against the rear face 106.

Depending on the nature of the carrier polymer used, cell 100 is subjected to a step of debinding, the duration of which varies between approximately 12 hours and 36 hours, and preferentially between 18 hours and 30 hours, at a temperature of between approximately 300° C. and 600° C., and preferentially between approximately 400° C. to 500° C. In the example described here, the step of debinding is accomplished in a resistance furnace for approximately 24 hours, at a temperature equal to approximately 450° C.

The structure obtained at the outcome of the step of debinding is subjected to a step of fritting, the duration of which varies between approximately 1 hour and 8 hours, preferentially between approximately 3 hours and 6 hours, at a temperature of between approximately 1000° C. and 1350° C., and preferentially between approximately 1200° C. and 1300° C. In the example described here, the step of fritting is accomplished for approximately 4 hours at 1300° C.

These steps of debinding and/or of fritting are preferably accomplished in a reducing atmosphere, preferentially in hydrogen or hydrogenated argon to allow core hydrogenation of the silicon of the photovoltaic cell 100.

1-14. (canceled)

15. A photovoltaic cell comprising:
a substrate composed of a semiconductor of a first type of conductivity including two main faces that are substantially parallel with one another,
wherein the substrate includes a plurality of blind holes, openings of which are located in a single one of the two main faces, and wherein the blind holes are filled by a semiconductor of a second type of conductivity opposed to the first type of conductivity forming an emitter of the photovoltaic cell, wherein the substrate forms a base of the photovoltaic cell; and
on the main face of the substrate including the openings of the blind holes, first collector pins composed of at least one semiconductor of the second type of conductivity in contact with the emitter of the photovoltaic cell, and second collector pins composed of at least one semiconductor of the first type of conductivity in contact with the substrate and interdigitated with the first collector pins.

16. The photovoltaic cell according to claim 15, in which each blind hole has a central axis of symmetry that is perpendicular to the two main faces of the substrate.

17. The photovoltaic cell according to claim 15, in which each blind hole includes, in a plane passing through the main face of the substrate including the openings of the blind holes, a section of area greater than an area of a bottom wall of the blind hole.

18. The photovoltaic cell according to claim 17, in which, for each blind hole, a ratio between an area of a section of the blind hole in an area of the plane passing through the main face of the substrate where the openings of the blind holes are located and the area of the bottom wall of the blind hole is between 1 and 3.

19. The photovoltaic cell according to claim 15, in which each blind hole has a truncated conical or ogival shape.

20. The photovoltaic cell according to claim 15, in which each blind hole has, in a plane parallel to one of the main faces of the substrate, a section of polygonal shape.

21. The photovoltaic cell according to claim 15, in which at least one of the main faces of the substrate is structured.

22. The photovoltaic cell according to claim 15, in which doping atoms concentration per cubic centimeter in the semiconductor of the second type of conductivity of the emitter is between 10¹⁶ and 10²¹, or between 10¹⁸ and 10²⁰, and doping atoms concentration per cubic centimeter in the semiconductor of the first type of conductivity of the substrate is between 10¹⁵ and 10¹⁸, or between 10¹⁶ and 10¹⁷.

23. The photovoltaic cell according to claim 15, in which the thickness of the substrate is less than 300 μm and the depth of each blind hole is greater than half the thickness of the substrate.

24. The photovoltaic cell according to claim 15, in which the doping atoms concentrations per cubic centimeter in the semiconductors of the first type of conductivity of the second collector pins and of the second type of conductivity of the first collector pins is between 10¹⁹ and 10²¹.

25. A method for producing a photovoltaic cell, comprising:
a) production of a substrate composed of a semiconductor of a first type of conductivity having two main faces that are parallel one with the other;
b) production of a plurality of blind holes in the substrate, such that openings of the blind holes are positioned in one only of the two main faces;
c) filling of the blind holes by a material composed of a semiconductor of a second type of conductivity, opposed to the first type of conductivity, forming an emitter of the photovoltaic cell;
in which the c) filling also produces, on the main face of the substrate where the openings of the blind holes are located, and through a first mask placed against the face of the substrate having the openings of the blind holes, first collector pins composed of at least one semiconductor of the second type of conductivity in contact with the emitter of the cell; and
d) removal of the first mask and production of second collector pins composed of at least one semiconductor of the first type of conductivity in contact with the substrate and interdigitated with the first collector pins by injection through a second mask placed against the face of the substrate where the openings of the blind holes are located.

26. The method according to claim 25, in which the a) production is implemented by an injection of a material composed of a semiconductor of the first type of conductivity into a mold.

27. The method according to claim 25, in which the substrate and/or the emitter and/or the collector pins are produced from a blend of materials composed of semiconductor and polymers powders, and the method further comprises, after the c) filling, a debinding of the blend undertaken at a temperature of between 300° C. and 600° C., over a period of between 12 hours and 36 hours, and fritting of powders obtained after debinding accomplished at a temperature of between 1000° C. and 1350° C., over a period of between 1 hour and 8 hours.

28. The method according to claim 27, in which the debinding and/or the fritting are undertaken in a reducing atmosphere.
